(19) United States
(12) Patent Application Publication
(10) Pub. No.: US 2011/0266048 A1
(43) Pub. Date: Nov. 3, 2011

(54) HOUSING AND METHOD FOR MANUFACTURING SAME

(75) Inventors: KAI-RONG LIAO, Shenzhen (CN); CHUAN-SHENG LI, Shenzhen (CN); CHI-CHUANG HO, Shindian (TW); YUNG-TA LO, Shindian (TW); YI-CHENG WANG, Shenzhen (CN); SHIH-WEI YANG, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 12/974,071

(22) Filed: Dec. 21, 2010

(30) Foreign Application Priority Data
Apr. 28, 2010 (CN) 201010158354.0

(51) Int. Cl. H01L 23/06; B29C 45/17; B29C 45/14

(52) U.S. Cl. 174/565; 264/271.1; 264/138

(57) ABSTRACT

A housing is for an electronic device. The housing includes a main body made of thermoplastic, and a transparent layer formed on the main body. The transparent layer is made of transparent thermosetting plastic.

### BACKGROUND

1. Technical Field

The disclosure relates to housings and methods for manufacturing the housings.

2. Description of Related Art

With the development of wireless communication and information processing technology, portable electronic devices, such as mobile telephones and electronic notebooks are now in widespread use. The external appearance of the housing of the portable electronic device can be one of the key factors in attracting consumers.

A typical way to achieve an attractive, three-dimensions external appearance is by using an insert molding process. Insert molding involves placing the preformed item made of thermoplastic in a mold, then inserting a transparent thermoplastic material, such as polymer, into the mold to contact at least part of the preformed item. Then, the transparent thermoplastic material is cooled and forms a transparent layer on the preformed item. Thus, the item will have an attractive, three-dimensional appearance. However, when the transparent thermoplastic material is added, the preformed item may deform as the thermoplastic material sets by heating.

Therefore, there is room for improvement within the art.

### BRIEF DESCRIPTION OF THE DRAWINGS

Many aspects of the exemplary housing and method for manufacturing the housing can be better understood with reference to the following drawings. These drawings are not necessarily drawn to scale, the emphasis instead being placed upon clearly illustrating the principles of the exemplary housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 is a schematic view of a housing according to an exemplary embodiment.

FIG. 2 is a cross-sectional view of the housing in FIG. 1.

FIG. 3 is a schematic view of a preformed item for manufacturing the housing in FIG. 1.

FIG. 4 is another view of the preformed item in FIG. 3 from another aspect.

FIG. 5 is a schematic view of an exemplary mold for manufacturing the housing in FIG. 1.

FIG. 6 is a schematic view when the preformed item is located in the mold.

FIG. 7 is a cross-sectional view of the mold and the preformed item in FIG. 6 along the line of IV-IV.

### DETAILED DESCRIPTION

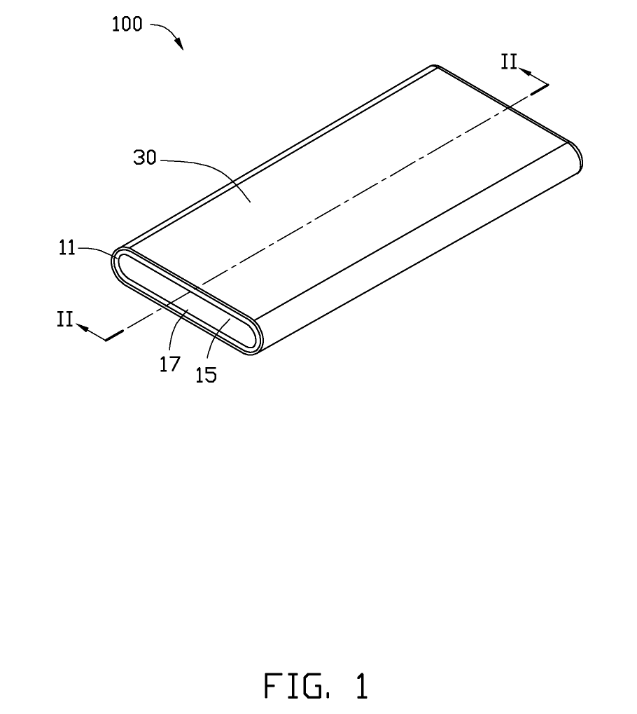

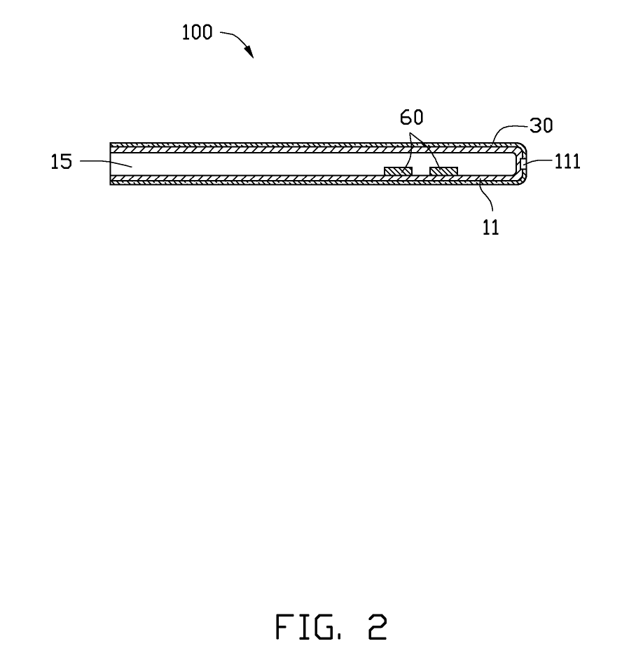

An exemplary embodiment of a housing 100 is shown in FIGS. 1 and 2. The housing 100 may be used for an electronic device, such as a mobile phone. The housing 100 includes a main body 11 and a transparent layer 30. The transparent layer 30 is formed on an outer surface of the main body 11. The main body 11 is tubular, and includes a chamber 15 and an opening 17 communicating with the chamber 15. The chamber 15 houses electronic components 60 received through the opening 17. The main body 11 may be made of thermoplastic. The transparent layer 30 is made of transparent thermosetting plastic, such as epoxy resin, phenolic resin, or unsaturated polyester resin. The transparent layer 30 is molded on the main body 11 by injection of transparent thermosetting plastic into a mold holding the main body 11. The transparent layer 30 has a thickness of about 0.3 micrometers to about 1.2 micrometers.

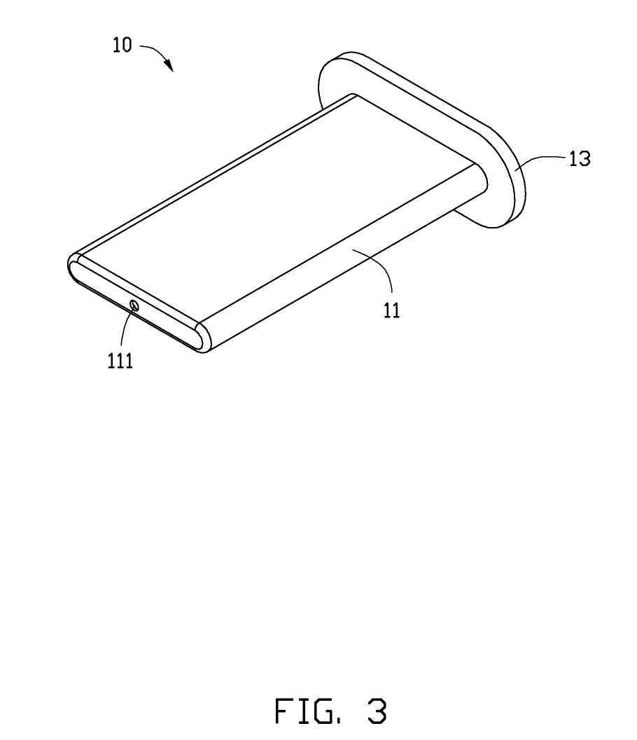

Referring to FIGS. 3-7, a method for manufacturing the housing 100 may include at least the following steps.

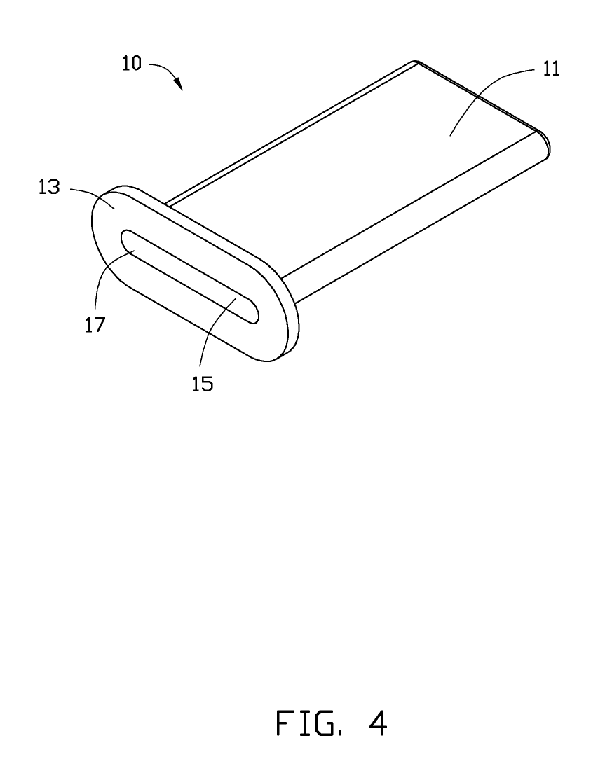

Referring to FIGS. 3 and 4, a preformed item 10 is provided. The preformed item 10 includes a main body 11, and a shoulder 13 protruding from one end of the main body 11 and surrounding the one end. The main body 11 is tubular and includes the chamber 15 and the opening 17. The preformed item 10 further defines a positioning hole 111 at the other end of the main body 11, opposite to the shoulder 13. The preformed item 10 may be molded using thermoplastic.

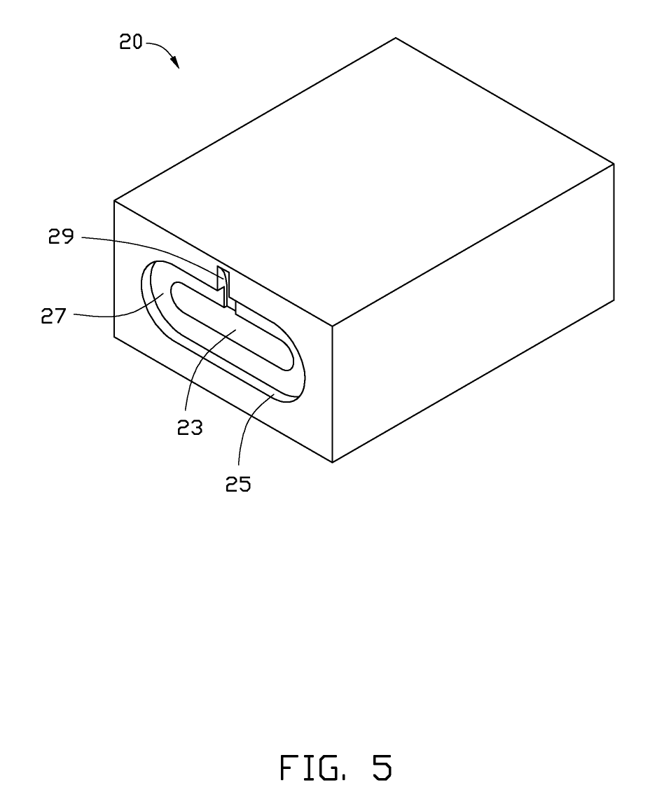

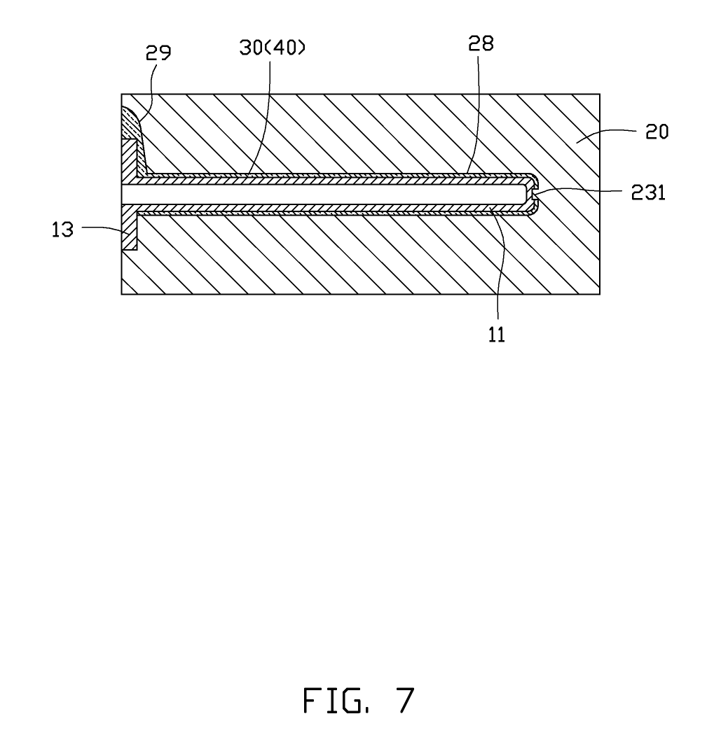

Referring to FIG. 5, a mold 20 is provided. The mold 20 defines a receiving groove 25 having the same shape and size as the shoulder 13, and a mold cavity 23 at the bottom wall of the receiving groove 25. The mold cavity 23 has the same shape as, but is larger than, the main body 11 of the preformed item 10. The mold 20 further includes a flange 27 formed between the receiving groove 25 and the mold cavity 23. When the shoulder 13 is received in the receiving groove 25, the shoulder 13 resists the flange 27. The mold 20 further defines a runner channel 29 near the receiving groove 25. The runner channel 29 communicates with the mold cavity 23 and for injecting thermosetting plastic into the mold cavity 23. Referring to FIG. 7, the mold 20 further includes a positioning pole 231 protruding from the bottom wall of the mold cavity 23. The positioning pole 231 mates with the positioning hole 111 so the main body 11 can be precisely positioned in the mold cavity 23.

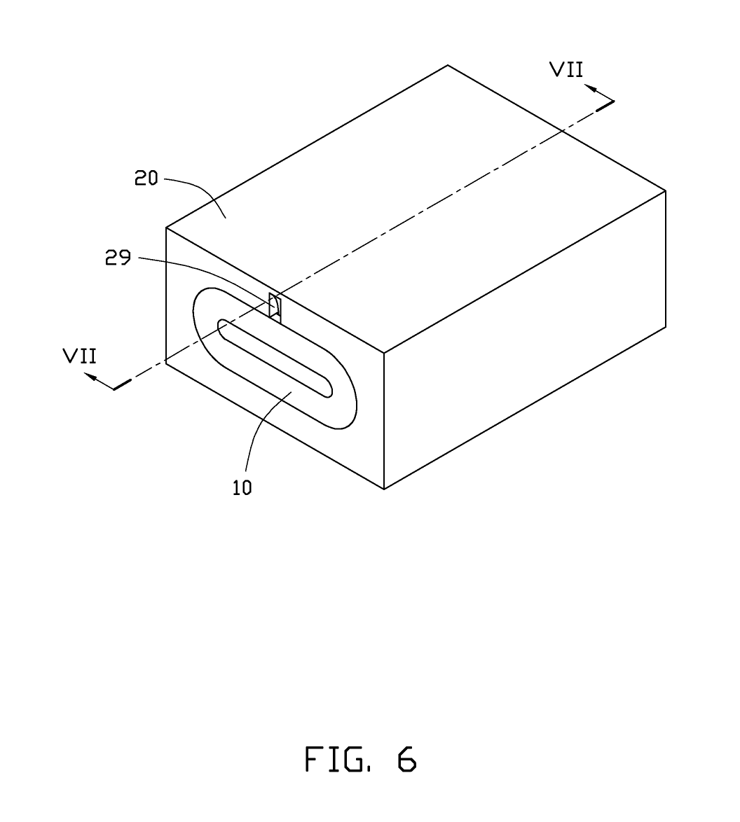

Referring to FIGS. 6 and 7, the main body 11 is inserted in the mold cavity 23. The shoulder 13 is accommodated in the receiving groove 25 and resists the flange 27. The positioning pole 231 is accommodated in the positioning hole 111. When the main body 11 is located in the mold cavity 23, a compartment 28 is defined between the main body 11 and the mold 20.

Referring to FIG. 7, transparent thermosetting plastic 40 is provided. The transparent thermosetting plastic 40 may be epoxy resin, phenolic resin, or unsaturated polyester resin. Included in the transparent thermosetting plastic 40 may be a corresponding curing agent, such as an amine, anhydride, or glyoxaline in the case of epoxy resin; ethyl sulfate in the case of phenolic resin; or hydrogen peroxide in the case of unsaturated polyester resin. Liquid transparent thermosetting plastic 40 is injected into the compartment 28 through the runner channel 29 until the liquid transparent thermosetting plastic 40 contacts all the surfaces of the main body 11 that will have the transparent layer 30 formed thereon.

The liquid transparent thermosetting plastic 40 may be set by heating the mold 20 until the transparent thermosetting plastic 40 is set. After the transparent thermosetting plastic 40 is set, a transparent layer 30 (see FIG. 7) is formed on the main body 11. The transparent layer 30 has a thickness from about 0.3 micrometer to about 1.2 micrometer.

The preformed item 10 and the transparent layer 30 are removed from the mold 20. Then, the shoulder 13 is cut off to yield a housing 100.

It is to be understood that a releasing agent (e.g., teflon coating) may be coated in the mold cavity 23 and the receiving groove 25, so the transparent layer 30 and the preformed item 10 can be more easily removed from the mold 20.

In this disclosure, the transparent layer 30 is formed on the main body 11 by setting transparent thermosetting plastic on the main body 11, and not injecting thermoplastic on the main body 11, thereby preventing the main body 11 from deformation by the thermoplastic. Additionally, an attractive, three-dimensions appearance will appear on the main body 11 when viewed through the transparent layer 30.

It is to be understood, however, that even through numerous characteristics and advantages of the exemplary embodiments have been set forth in the foregoing description, together with details of the structure and function of the invention, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing for an electronic device, comprising:
a main body made of thermoplastic; and
a transparent layer formed on the main body, the transparent layer being made of transparent thermosetting plastic.

2. The housing as claimed in claim 1, wherein the transparent layer is formed on an outer surface of the main body and surrounding the main body.

3. The housing as claimed in claim 2, wherein the main body is tubular, and includes a chamber and an opening communicating with the chamber.

4. The housing as claimed in claim 1, wherein the transparent thermosetting plastic is epoxy resin, phenolic resin, or unsaturated polyester resin.

5. The housing as claimed in claim 1, wherein the transparent layer has a thickness from about 0.3 micrometers to about 1.2 micrometers.

6. A method for manufacturing a housing of an electronic device, comprising:
providing a preformed item;
providing a mold defining a mold cavity;
inserting the preformed item in the mold cavity to form a compartment between the preformed item and the mold;
injecting liquid transparent thermosetting plastic into the compartment;
curing the transparent thermosetting plastic to form a transparent layer on an outer surface of the preformed item.

7. The method as claimed in claim 6, wherein the preformed item includes a main body, and a shoulder protruding from one end of the main body and surrounding the main body;
the transparent layer being formed on the main body.

8. The method as claimed in claim 7, further comprising removing the preformed item and the transparent layer from the mold, and cutting off the shoulder to yield the housing.

9. The method as claimed in claim 8, wherein the preformed item further defines a positioning hole at the end of the main body opposite to the shoulder; the mold further comprising a positioning pole protruding from the bottom wall of the mold cavity; mating the positioning pole with the positioning hole to position the main body can be precisely received in the mold cavity.

10. The method as claimed in claim 8, wherein the mold further defines a receiving groove for accommodating the shoulder, the mold cavity being defined at the bottom wall of the receiving groove.

11. The method as claimed in claim 8, wherein the mold cavity has the same shape as, but is larger than, the main body of the preformed item.

12. The method as claimed in claim 11, wherein the mold further includes a flange formed between the receiving groove and the mold cavity; when the shoulder is received in the receiving groove, the shoulder resisting the flange.

13. The method as claimed in claim 12, wherein the mold further defines a runner channel near the receiving groove and communicating with the mold cavity for injecting liquid thermosetting plastic into the mold cavity.

14. The method as claimed in claim 6, wherein the transparent thermosetting plastic is epoxy resin, phenolic resin, or unsaturated polyester resin.

15. The method as claimed in claim 14, wherein when the transparent thermosetting plastic is epoxy resin, using an amine, anhydride, or glyoxaline as curing agent.

16. The method as claimed in claim 14, wherein when the transparent thermosetting plastic is phenolic resin, using ethyl sulfate as curing agent.

17. The method as claimed in claim 14, wherein when the transparent thermosetting plastic is unsaturated polyester resin, using hydrogen peroxide as curing agent.

18. The method as claimed in claim 6, wherein the transparent thermosetting plastic is set by heating the mold until the transparent thermosetting plastic is set.

19. The method as claimed in claim 6, wherein the transparent layer has a thickness from about 0.3 micrometers to about 1.2 micrometers.
